(19) United States
(12) Patent Application Publication
(10) Pub. No.: US 2026/0235687 A1
(43) Pub. Date: Aug. 13, 2026

(54) ENERGY STORAGE CIRCUIT

(71) Applicant: Renesas Electronics America Inc., Milpitas, CA (US)

(72) Inventor: Swaminathan NARAYANASWAMY, Munich (DE)

(73) Assignee: Renesas Electronics America Inc., Milpitas, CA (US)

(21) Appl. No.: 19/049,091

(22) Filed: Feb. 10, 2025

(51) Int. Cl. G01R 31/389; H01M 10/0525; H01M 10/42; H01M 10/48

(52) U.S. Cl. CPC G01R 31/389; H01M 10/0525; H01M 10/425; H01M 10/482; H01M 2010/4271

(57) ABSTRACT

An energy storage circuit is provided. The energy storage circuit includes a battery module formed of a plurality of battery cells, a current sense resistor, and a controller. Each battery cell is coupled to a corresponding cell resistor via a switch. The controller is operable to arrange the switches in a first configuration to perform an impedance measurement of one or more battery cells in the battery module. In the first configuration the cell resistors are coupled in series with each other and with the current sense resistor.

### TECHNICAL FIELD

The present disclosure relates to an energy storage circuit, and in particular to a battery-based energy storage circuit. More specifically, the disclosure relates to an energy storage circuit comprising a battery module and a controller configured to perform an impedance measurement of one or more battery cells in the battery module.

### BACKGROUND

Impedance measurement such as electrochemical impedance spectroscopy (EIS) can be used to check the status of batteries cells including State-of-Charge (SoC) and State-of-Health (SoH). The impedance measurement can also be used to determine the core temperature of the battery cells that is significantly different than the surface temperature measured using temperature sensors.

In an energy storage system such as a battery pack formed of several battery modules connected in series, the battery cell properties may be assessed at individual battery cell level, or at module level, or at the battery pack level.

The module-level approach does not contain the complexities of pack-level techniques, namely integration of the excitation circuit and the strict time synchronization requirement between the current and voltage measurement from different sensors. Compared to the cell-level approach, the module-level approach is more cost-effective because no additional wiring is required between the battery cells and the excitation signal source. Yet, current systems for module-level EIS measurement require a dedicated EIS excitation circuitry. In addition the excitation current needed for measuring the cell impedance is very high.

It is an object of the disclosure to address one or more of the above mentioned limitations.

### SUMMARY

According to a first aspect of the disclosure, there is provided an energy storage circuit comprising a battery module formed of a plurality of battery cells, wherein each battery cell is coupled to a corresponding cell resistor via a switch; a current sense resistor; and a controller configured to control the switches; wherein the controller is operable to arrange the switches in a first configuration to perform an impedance measurement of one or more battery cells in the battery module; wherein in the first configuration the cell resistors are coupled in series with each other and with the current sense resistor.

For instance, in the first configuration the controller may be operable to perform an impedance measurement for each individual battery cell in the battery module. The cell resistors may be bleeding resistors, or discharge resistors.

Optionally, the controller is operable to arrange the switches in a second configuration to balance charges of individual battery cells.

Optionally, the battery cells are connected in series along a first conducting channel, and the cell resistors are connected in series along a second conducting channel; and wherein for each battery cell the switch is provided along a third conducting channel intersecting both the first conducting channel and the second conducting channel.

Optionally, the energy storage circuit comprises an additional switch provided along an additional conducting channel intersecting both the first conducting channel and the second conducting channel.

Optionally, each battery cell has a first terminal and a second terminal and wherein the first terminal is coupled to the cell resistor via the switch and a second terminal is coupled to the cell resistor via another switch from a next battery cell.

For instance the first terminal may be an anode and the second terminal a cathode or the other way round.

Optionally, the controller is configured to provide a switch control signal for generating an excitation signal, and to measure a response signal in response to the excitation signal.

For example, the excitation signal may be a current and the response signal a voltage. Alternatively, the excitation signal may be a voltage, and the response signal a current.

Optionally, wherein in the first configuration, the switch control signal is used to control one switch among the plurality of switches, and wherein the other switches are turned off apart from the additional switch which is turned on.

Optionally, wherein in the first configuration the excitation signal is a current that flows through the cell resistors and the current sense resistor.

Optionally, wherein the controller is configured to measure a voltage across the current sense resistor to derive the current, and to measure a set of voltages across individual battery cells.

Optionally, wherein the controller is configured to calculate the impedance of each battery cell in the module based on the current and the set of voltages across individual battery cells.

Optionally, wherein the switch control signal is a sinusoidal signal.

Optionally, wherein in the second configuration, at least one battery cell in the module is independently discharged via the cell resistor.

Optionally, wherein the impedance measurement of each battery cell is performed in parallel and/or simultaneously for all the battery cells in the module.

Optionally, wherein the controller is configured to perform electrochemical impedance spectroscopy (EIS).

Optionally, wherein the battery cells are Lithium-Ion cells.

According to a second aspect of the disclosure, there is provided an energy storage system comprising a plurality energy storage circuits according to the first aspect.

Optionally, wherein the plurality of energy storage circuits is coupled to a master controller via a communication interface.

For instance the master controller may be a microcontroller (MCU).

Optionally, wherein the energy storage circuits are connected in series to form a battery pack.

According to a third aspect of the disclosure there is provided a method of performing an impedance measurement of one or more battery cells in a battery module, wherein each battery cell is coupled to a corresponding cell resistor via a switch; the method comprising:
providing a current sense resistor;
providing a controller configured to control the switches; and
operating the controller to arrange the switches in a first configuration to perform the impedance measurement of the one or more battery cells; wherein in the first configuration the cell resistors are coupled in series with each other and with the current sense resistor.

Optionally, the method comprises providing a switch control signal for generating an excitation signal, and measuring a response signal.

### DESCRIPTION OF THE DRAWINGS

The disclosure is described in further detail below by way of example and with reference to the accompanying drawings, in which:

FIG. 1 is a schematic diagram of a battery pack;

FIG. 2 is a diagram of a high-voltage Lithium-Ion battery pack;

FIG. 3 is a diagram of a conventional passive cell balancing circuit architecture;

FIG. 4 is a flow diagram of a method for performing an impedance measurement of a battery module according to the disclosure; and

FIG. 5 is an energy storage circuit according to the disclosure.

### DESCRIPTION

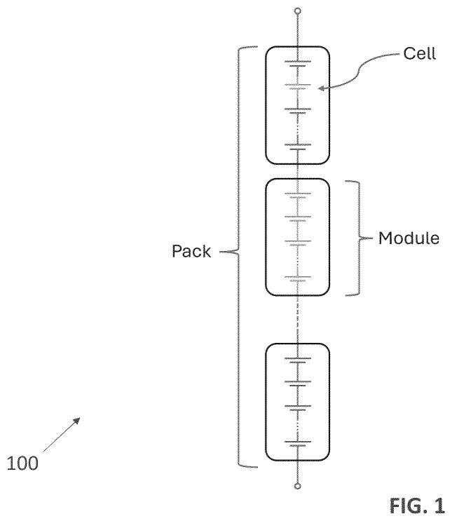

FIG. 1 is a schematic diagram of a battery pack, such as a Lithium-Ion battery pack. The battery pack 100 includes multiple Lithium-Ion cells in series, that create several modules. The modules are then coupled in series to create the pack.

Impedance values of the battery cells can be measured by using a technique called electrochemical impedance spectroscopy (EIS). Here, the battery cells are excited with either a time varying current or voltage signal and the corresponding time varying voltage or current response is measured respectively. The ratio of the time varying voltage to the time varying current is the complex impedance of the battery cell. Typically the excitation signal is a time varying current signal and the corresponding time varying voltage response of the cells are measured to calculate the complex AC impedance.

Impedance measurement may be used to assess the state or status of individual cells in the battery pack. The excitation signal for the EIS measurements can be at different levels: i) Pack-level, ii) Cell-level and iii) Module-level.

In the pack level EIS a single AC excitation signal is applied in series to all the cells in the pack and the response of all the cells towards this excitation signal is measured.

The excitation signal source could either be a separate signal source or could be integrated with other systems in the application. In the case of electric vehicle (EV) applications, the pack-level excitation signal could be integrated in either On-board Charger (OBC) or DC/DC converter or Inverter or in pre-charge circuit.

This method has the benefit that the excitation signal is applied to the cells only once and the impedance of all the cells in the battery pack can be measured at the same time. The drawback of this approach is the high complexity involved in integrating the excitation signal with other systems in the application. Moreover, the measurement of excitation current and the voltage response from the cells must have a strict time synchronization, which further increases the complexity of the pack-level EIS approaches, since the current measurement and the cell voltage measurements are performed by different modules in the system.

In contrast to the pack-level EIS approach, the cell-level EIS methodology applies the excitation signal directly to each cell in a series-connected Lithium-Ion battery pack. Here the existing passive cell balancing network made of a discharge resistor and a switch is used to generate the excitation signal. Low-cost and low-complexity due to the usage of existing components for EIS measurements are the benefits of this approach.

One of the biggest drawbacks of the cell-level approach is that the impedance of the cables connecting the battery cell, and the passive balancing network is significantly larger than the impedance of the battery cell itself and results in errors in the impedance measurement of the battery cell. To overcome this issue, additional low-impedance connection cables are needed to connect the battery cell and the passive balancing network, increasing the overall cost of the approach. Moreover, the impedance of all the cells cannot be measured at the same time resulting in an increased overall impedance profiling time of the system. In addition, the excitation current is not actively measured and is only programmed by the Battery Management System (BMS) controller. Parasitic circuit components in the current flow path are different for each cell and therefore might not produce the same current as set by the BMS controller. This will lead to errors in the measured impedance of the cells.

The module level EIS approach does not increase the complexity compared to pack-level technique by simplifying the integration of the excitation source and also enabling synchronized measurement of excitation current and cell voltage response. Compared to the cell-level EIS technique the module-level approach is more cost-effective because no additional wiring is required between the battery cells and the excitation signal source.

### However, Current Systems for Module Level Eis Measurement Require a Dedicated Eis

excitation circuitry.

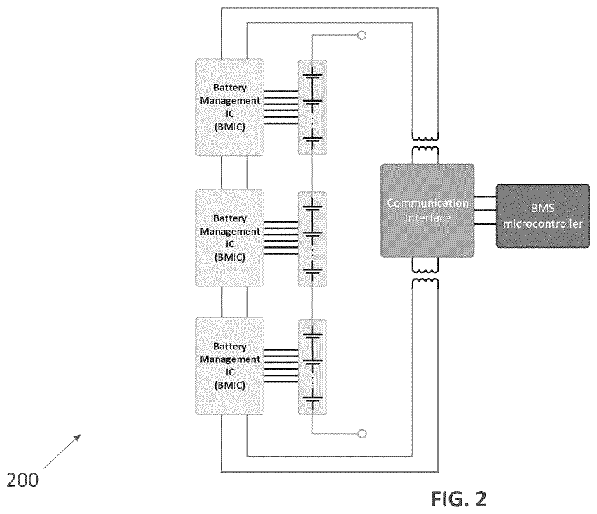

FIG. 2 is a diagram showing the structure of a high-voltage Lithium-Ion battery pack typically used in EV applications or in stationary Energy Storage Systems (ESS). Multiple Lithium-Ion cells are connected in series and grouped to form a module, which in turn are connected in series to form a battery pack achieving the required operation voltage. Lithium-Ion cells are required to be maintained within a safe operating area determined by voltage, temperature, pressure and current. Violating the safe operating conditions would reduce the lifetime of the cells and could result in thermal runaway situations which in turn may lead to fire or explosion. A Battery Management System (BMS) is used to monitor several parameters including voltage, temperature, and pressure of each cell in the battery pack and ensures safe operating conditions. In addition, the BMS also computes the state parameters of the battery pack, namely, the State-of-Charge (SoC) and the State-of-Health (SoH) and isolates the battery pack in case of fault.

The BMS is made of multiple Battery Monitoring Integrated Circuit (BMIC) that measures and monitors the parameters of the cells in a module, as shown in FIG. 2. The BMICs monitor the voltage, temperature and pressure of the cells in the module. The BMICs communicate with each other and to the BMS master controller through a daisy-chain communication link to exchange the measured voltages and temperatures of the cells, that are used to calculate the SoC and SoH by the master controller. In addition, the BMICs promptly report any fault in any cell within the module to the master controller so that the battery pack can be safely shutdown.

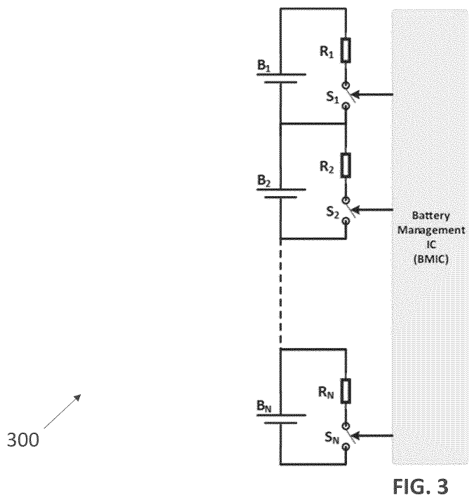

FIG. 3 is a diagram of a conventional passive cell balancing circuit architecture.

The passive cell balancing circuit is made of a high-power resistor, also referred to as bleeding resistor connected to the battery cell using a switching element. For instance for the cell B1, the bleeding resistor R1 is coupled to B1 via the switch S1.

When the SoC of any cell in the series-connected battery pack is higher than the rest of the cells then the excess energy is discharged through the bleeding resistor by turning ON the switching element.

The bleeding resistor can only be connected to a single cell. As a result, the passive balancing architecture of FIG. 3 can only be utilized for performing cell-level EIS.

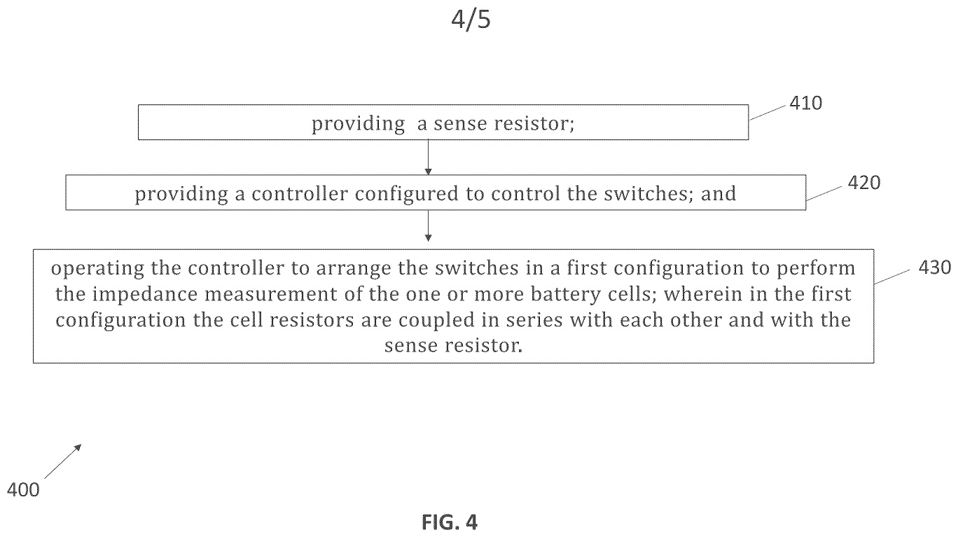

FIG. 4 is a flow diagram of a method for performing an impedance measurement of a one or more battery cells in a battery module, according to the disclosure. The battery module, also referred to as battery set, is formed of a plurality of battery cells connected in series. Each battery cell is coupled to a corresponding cell resistor via a switch. The cell resistors may be bleeding resistors, or discharge resistors.

At step 410 a sense resistor, also referred to as current sense resistor or shunt resistor is provided. At step 420 a controller configured to control the switches is provided. At step 430 the controller is operated to arrange the switches in a first configuration to perform an impedance measurement of the one or more battery cells. In the first configuration the cell resistors are coupled in series with each other and with the sense resistor.

For instance, in the first configuration the controller may be operable to perform an impedance measurement of each individual battery cell in the battery module. This may be performed in parallel or sequentially.

The impedance measurement may be obtained by generating an excitation signal and measuring a response signal in response to the excitation signal.

For example, the excitation signal may be a current and the response signal a voltage. For instance, various sinusoidal currents at different frequencies may be used to excite the battery cells. Alternatively, the excitation signal may be a voltage, and the response signal a current.

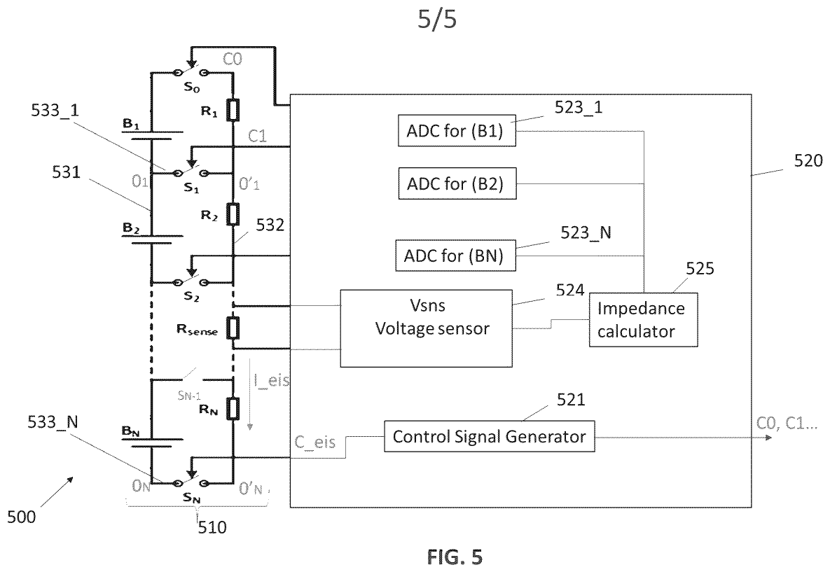

FIG. 5 is an energy storage circuit according to the disclosure. The energy storage circuit 500 includes a battery module 510 formed of a plurality N battery cells B₁-B_{N} connected in series. The battery cells may be implemented in different ways, for instance the battery cells may be Lithium-Ion cells. Each battery cell B₁-B_{N} is coupled to a corresponding cell resistor R₁-R_{N} via two switching elements. The resistors R₁-R_{N} may also be referred to as bleeding resistors, as they can be used to discharge the cell. For instance, the bleeding resistor R₁ is connected to cell B₁ via switches S₀ and S₁ and resistor R₂ is connected to cell B₂ via S₁ and S₂. The circuit 500 also includes a sense resistor Rsense and a controller 520 configured to control the switches of each battery cell.

The controller 520 is operable to arrange the switches S₀-S_{N} in a first configuration to perform an impedance measurement of the battery cells. In the first configuration the cell resistors R₁-R_{N} are coupled in series with each other and with the sense resistor Rsense. The impedance measurement may be electrochemical impedance spectroscopy (EIS).

The controller 520 has a control signal generator 521 for generating the control signals C0-CN-1 controlling the switches S₀-S_{N-1}, and the control signal C_eis for generating the excitation signal (in this case the current I_eis). The control signal C_eis may be a sinusoidal signal. The controller 520 also includes a plurality of voltages sensors 523_1-523_N for sensing the voltages of the individual cells. For instance, the voltage sensors may be implemented as ADC sensors. Another voltage sensor 524 is provided to measure the voltage Vsns across Rsense. The controller 520 also includes an impedance calculator 525. The impedance calculator may be configured to implement various types of impedance measurements, for instance various types of EIS techniques.

The controller 520 may be a BMIC. Typically, BMICs already include EIS excitation circuitry; therefore there is no need for an additional dedicated EIS excitation circuitry.

The battery cells B₁-B_{N} are connected in series along a first conducting channel 531. Similarly the cell resistors R₁-R_{N} are connected in series along a second conducting channel 532. For each battery cell B₁-B_{N} the switch S is provided along a third conducting channel 533 intersecting both the first conducting channel 531 and the second conducting channel 532.

For instance, for cell B₁ the switch S₁ is provided along the third conducting channel 533_1 between the nodes 0₁ and 0₁′.

Similarly, for cell B_{N} the switch S_{N} is provided along the third conducting channel 533_N between the nodes 0_{N} and 0_{N}′.

Optionally, the energy storage circuit may include an additional switch S₀ provided along an additional third conducting channel.

By adding the switch S₀ to cell B₁, the topology allows both passive cell balancing and module-level impedance measurement.

In this case each battery cell has a first terminal (for instance a cathode) coupled to the cell resistor R via the switch S and a second terminal (for instance an anode) coupled to the cell resistor R via another switch S from a next battery cell or S₀.

For instance, the cell B_{N} has a cathode (positive terminal) coupled to the cell resistor R_{N} via the switch S_{N-1} from battery cell B_{N-1} and an anode (negative terminal) coupled to the cell resistor R_{N} via the switch S_{N}.

The cell B₁ has a cathode coupled to the cell resistor R₁ via the additional switch S₀ and an anode coupled to the cell resistor R₁ via the switch S₁.

In FIG. 5, the sense resistor Rsense is provided on the second conductive channel 532 just before R_{N}, however Rsense could be provided anywhere on the second conductive channel 532. For instance Rsense could be provided just after R_{N}. In this case Rsense would have a terminal coupled to the most negative potential of the module and another terminal coupled to R_{N}, making the current measurement easier.

The current sense resistor Rsense may be an external resistor, separate from the cells and distinct from the bleeding resistors. The purpose of Rsense is to be used for measuring current and it has a different value compared to the bleeding resistors R₁-R_{N}.

In operation, the controller may be operated to perform an impedance measurement (first configuration) or to perform cell balancing (second configuration).

In the first configuration, the controller 520 generates the control signal C_eis to perform an impedance measurement. The signal C_eis is used to control one switch among the plurality of switches, for instance the switch S_{N}. The controller 520 turns off (open) the other switches apart from the additional switch S₀ which is turned on (closed).

So the resistors R₁-R_{N} are coupled in series to form a single module-level resistor, that is in series with the sense resistor.

The control signal C_eis may be a sinusoidal signal generated by circuit 521 within the controller 520. This results in drawing a sinusoidal excitation current I_eis from all the cells in the module. The excitation current I_eis flows through the cell resistors R1-RN and the sense resistor Rsense. Various sinusoidal currents at different frequencies may be used to excite the battery cells.

The voltage sensor 524 coupled to Rsense measures the voltage Vsns across Rsense. The voltage Vsns is then used to derive a value of the excitation current I_eis. The impedance calculator 525 receives the set of cell voltages measured across individual battery cells, and the voltage Vsns, and calculates the impedance of the all the cells in the module. Stated another way, the impedance calculator 525 calculates the impedance of each individual cell.

The impedance measurement of each individual cell may be performed in parallel and/or simultaneously for all the cells in the module. Each cell has a dedicated voltage sensor (in the present example and ADC sensor). This permits the measurement of all cell voltages (voltage response) in the module simultaneously.

Various sinusoidal currents at different frequencies may be used to excite the battery cells. The impedances at these different frequencies may then be used to understand the properties of the battery cells.

The complex AC impedance may be used to calculate additional state properties of the battery cells (each individually), namely, State-of-Charge (SoC) and State-of-Health (SoH). Moreover, the impedance of battery cells also correlates to the internal temperature of the cells and by measuring the impedance accurately, one can determine the core temperature of the battery cells (each individually) that is significantly different than the surface temperature measured using temperature sensors.

In the second configuration, the controller arranges the switches to balance charges of individual battery cells. In this case a cell is connected to its corresponding bleeding resistor to dissipate the excess charge as heat.

For instance, by closing the switches S₀ and S₁, the cell B₁ can be balanced separately from the other cells. To balance the cell B₂, the switch S₀ is opened and the switches S₁ and S₂ are closed. Similar switching schemes allow to balance individual cells within the module.

Therefore the resistors R₁-R_{N} may be used both to implement passive balancing of the cells in the module, as well as for performing the impedance measurement.

The circuit 500 enables performing a module-level impedance measurement such as EIS. By rearranging the connections of the bleeding resistor used for passive cell balancing, the circuit of FIG. 5 also provides significant cost savings and reduced footprint.

An energy storage system may be obtained by connecting a plurality energy storage circuits 500 together in series in the same fashion as shown in FIG. 2. In this case a master controller such as a microcontroller is connected to the plurality of modules via a communication interface.

The energy storage system may be used for different applications. For instance, the energy storage system may be implemented to form a battery pack.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. An energy storage circuit comprising:
a battery module formed of a plurality of battery cells, wherein each battery cell is coupled to a corresponding cell resistor via a switch;
a current sense resistor; and
a controller configured to control the switches,
wherein the controller is operable to arrange the switches in a first configuration to perform an impedance measurement of one or more battery cells in the battery module; and
wherein in the first configuration the cell resistors are coupled in series with each other and with the current sense resistor.

2. The energy storage circuit as claimed in claim 1, wherein the controller is operable to arrange the switches in a second configuration to balance charges of individual battery cells.

3. The energy storage circuit as claimed in claim 1, wherein:
the battery cells are connected in series along a first conducting channel, and the cell resistors are connected in series along a second conducting channel; and
for each battery cell the switch is provided along a third conducting channel intersecting both the first conducting channel and the second conducting channel.

4. The energy storage circuit as claimed in claim 3, further comprising an additional switch provided along an additional conducting channel intersecting both the first conducting channel and the second conducting channel.

5. The energy storage circuit as claimed in claim 3, wherein each battery cell has a first terminal and a second terminal and wherein the first terminal is coupled to the cell resistor via the switch and a second terminal is coupled to the cell resistor via another switch from a next battery cell.

6. The energy storage circuit as claimed in claim 4, wherein the controller is configured to provide a switch control signal for generating an excitation signal, and to measure a response signal in response to the excitation signal.

7. The energy storage circuit as claimed in claim 6, wherein in the first configuration, the switch control signal is used to control one switch among the plurality of switches, and wherein the other switches are turned off apart from the additional switch which is turned on.

8. The energy storage circuit as claimed in claim 7, wherein in the first configuration the excitation signal is a current that flows through the cell resistors and the current sense resistor.

9. The energy storage circuit as claimed in claim 8, wherein the controller is configured to measure a voltage across the current sense resistor to derive the current, and to measure a set of voltages across individual battery cells.

10. The energy storage circuit as claimed in claim 9, wherein the controller is configured to calculate the impedance of each battery cell in the module based on the current and the set of voltages across individual battery cells.

11. The energy storage circuit as claimed in claim 6, wherein the switch control signal is a sinusoidal signal.

12. The energy storage circuit as claimed in claim 2, wherein in the second configuration, at least one battery cell in the module is independently discharged via the cell resistor.

13. The energy storage circuit as claimed in claim 1, wherein the impedance measurement of each battery cell is performed in parallel and/or simultaneously for all the battery cells in the module.

14. The energy storage circuit as claimed in claim 1, wherein the controller is configured to perform electrochemical impedance spectroscopy (EIS).

15. The energy storage circuit as claimed in claim 1, wherein the battery cells are Lithium-Ion cells.

16. An energy storage system comprising a plurality energy storage circuits as claimed in claim 1.

17. The energy storage system as claimed in claim 16, wherein the plurality of energy storage circuits is coupled to a master controller via a communication interface.

18. The energy storage system as claimed in claim 16, wherein the energy storage circuits are connected in series to form a battery pack.

19. A method of performing an impedance measurement of one or more battery cells in a battery module, wherein each battery cell is coupled to a corresponding cell resistor via a switch; the method comprising:
providing a current sense resistor;
providing a controller configured to control the switches; and
operating the controller to arrange the switches in a first configuration to perform the impedance measurement of the one or more battery cells; wherein in the first configuration the cell resistors are coupled in series with each other and with the current sense resistor.

20. The method as claimed in claim 19, further comprising:
providing a switch control signal for generating an excitation signal, and measuring a response signal.
